(19) United States
(12) Patent Application Publication
(10) Pub. No.: US 2003/0198898 A1
(43) Pub. Date: Oct. 23, 2003

(54) Method for manufacturing a semiconductor device

(76) Inventors: Shun-Li Lin, Hsinchu (TW); Chun-Yi Yang, Chu-Tong Town (TW)

Correspondence Address: J.C. Patents, Inc., 4 Venture, Suite 250, Irvine, CA, 92618, US

(21) Appl. No.: 10/125,227

(22) Filed: Apr. 17, 2002

(51) Int. Cl. G03F 7/16; G03F 7/20

(52) U.S. Cl. 430/315; 430/319; 430/950

(57) ABSTRACT

A method for fabricating a MOSFET structure having a source/drain extension and a source/drain region is disclosed, in which a basic antireflection coating is formed over a semiconductor substrate. A photoresist layer is formed over the basic antireflection coating. The photoresist layer is exposed to a radiation for transferring a pattern on the photoresist layer and the exposed photoresist layer is developed to form an opening over the areas for forming the source/drain regions, as a result a photoresist pattern with footing structures at a bottom comer of the photoresist pattern is formed. An ion implantation using the photoresist pattern as a mask, to simultaneously to form a source/drain extension and a source/drain region.

### BACKGROUND OF THE INVENTION

1. Filed of Invention

The present invention relates to a method for manufacturing a semiconductor device. More particularly, the present invention relates to a method of forming a source/drain extension in the fabrication of a MOS field effect transistor (MOSFET).

2. Description of Related Art

Device miniaturization can achieve faster, smaller, and more densely packed integrated circuit device in semiconductor device manufacturing. In scaling down devices, there is a need for a thinner gate oxide and higher doped channels for boosting the punch-through voltage of the short-channeled devices. Higher doped channels would drastically increase the electric field near the drain region which in turn accelerates charge carriers, what is commonly known as hot carriers, for overcoming the oxide barrier and inject into the gate. Unfortunately hot carriers under increased electric field could potentially induce damage to the gate oxide thereby degrading the performance of the devices. Therefore one way to suppress the short-channel effect is to reduce this electric field and this is possible by forming source/drain extension at the edges near the channel. According to a conventional scheme, the method for forming a source/drain extension and a source/drain region comprises a two-step ion implantation process. One of the ion implantation is self-aligned to the gate electrode using a lower energy to form a source/drain extension, and the second ion implantation is self aligned to the gate and the gate sidewall spacer using a higher energy to form a source/drain region. However the drawback of the above-mentioned prior art is that it requires two ion implantation steps thereby substantially increasing the fabrication cost.

### SUMMARY OF THE INVENTION

Accordingly, it is an object of the present invention to provide a method for forming a source/drain extension and a source/drain region in a MOSFET device, wherein the source/drain extension and source/drain regions are formed simultaneously through a single ion implantation step.

It is a further object of the present invention is to provide a simplified method for fabricating a MOSFET structure having a source/drain extension and a source/drain region, so that the fabrication cost can be reduced and the production through-put can be increased.

It is an object of the present invention is to provide an method for forming a source/drain extension in a MOSFET device so as to satisfy the device miniaturization design rule.

Accordingly, in order to achieve these and other objects and advantages, the present invention provides a method for fabricating a MOSFET structure having a source/drain extension and a source/drain region. A basic antireflection coating is formed over a semiconductor substrate. A photoresist layer is formed on the basic antireflection coating. The photoresist layer is exposed to a radiation for transferring a pattern on the photoresist layer and the exposed photoresist layer is developed to form an opening over the areas for forming the source/drain regions, as a result, a photoresist pattern with footing structure at a bottom comer region of the photoresist pattern is formed. An ion implantation is performed using the photoresist pattern as a mask to simultaneously form a source/drain extension and a source/drain region. The photoresist pattern and the antireflection coating are removed. A gate oxide layer and a polysilicon layer are sequentially formed over the substrate. Then, the polysilicon layer is patterned to form a gate above the desired channel regions.

An aspect of the present invention is that because the photoresist pattern having footing structure, the source/drain extension and source/drain region can be formed by a single ion implantation simultaneously, therefore the fabrication process is simplified and the fabrication cost can be reduced and also the production through-put can be increased.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1 through 4 is a schematic cross sectional view, showing the progression of manufacturing process for forming a MOSFET structure according to a preferred embodiment of the present invention.

### DESCRIPTION OF THE PREFERRED EMBODIMENTS

The present invention is directed to a method for fabricating a source/drain extension in a MOSFET structure. Referring to FIG. 1, according to a preferred embodiment of the present invention, a semiconductor substrate 100 is provided. An anti-reflection coating (ARC) 102 is formed over the semiconductor substrate 100. The function of ARC 102 is to prevent light reflection from the substrate during the photolithography process. The ARC 102 is important for forming a fine dimension pattern, as is well known to persons skilled in the art. The ARC 102 can be a bottom antireflection coating (BARC), or alternatively, the ARC 102 can be a dielectric antireflection coating (DARC).

Known examples of BARC are an inorganic coating type such as titanium, titanium dioxide, titanium nitride, chromium oxide, carbon and α-silicon, and an organic coating type comprising a light absorbent and a polymer material. The advantage of using an organic BARC is that both the photoresist layer and the BARC can be effectively removed by using for example, a conventional plasma ashing process.

Known example of DARC is a SiON DARC. The SiON DARC can be formed by a number of conventional techniques, including deposition of SiON in an ambient containing O2, NO, N2O, NH3, He, N2, or Ar.

The material of the ARC according to a preferred embodiment of the present invention, is preferably consisting of substantially chemically basic materials selected from one of, but not restricted to, above-mentioned BARC or DARC material. For a DARC composed of silicon oxynitride (SiOₓN_{y}), the alkalinity of the surface can be controlled by adjusting the ratio of x to y or by performing a surface treatment with O₂ plasma. When y is larger than x, for example, more ═N—H or >N—H groups exist on the surface of the DARC so that the surface is more basic. On the other hand, for a BARC composed of a light absorbent and a polymer material, the surface alkalinity can be controlled by adjusting the concentration of a polymer crosslinking agent in the BARC or by adjusting the baking temperature of the BARC. The BARC material with a alkalinity/acidity adjustable by the baking temperature includes AR2 manufactured by Shipley, which is basic with a baking temperature of 205° C. but is acidic with a baking temperature of 150° C. Within the temperature range of 150° C.˜205° C., the alkalinity (or acidity) of an AR2 BARC is stronger when the baking temperature is higher (or lower).

Still referring to FIG. 1, according to a preferred embodiment of the present invention, photoresist layer 104 is then spun over the ARC 102. It is well known in the art that in most applications, an acid-catalyzed photoresist composition is applied to a surface where a patterned photoresist is desired. Typically, the photoresist layer 104 is then exposed to radiation to cause generation of acid within the exposed areas of the photoresist layer 104. Acid-catalyzed photoresists are generally comprises an acid-sensitive polymer and a radiation-sensitive acid-generating compound (photosensitive acid generator or PAG). On exposure of the photoresist composition to a suitable radiation source, the PAG generates an acid to initiate a catalytic reaction with the acid-sensitive polymer. As a result of the reaction between the acid-sensitive polymer and the generated acid, the composition of the polymer in the exposed photoresist is altered relative to the same polymer in an unexposed photoresist composition such that the exposed photoresist can be selectively removed relative to the unexposed photoresist.

Most importantly, the present inventors observed that the amount of acid generated within photoresist layer 104 in the exposed area decreases with increasing depth due to decrease in the intensity of incident radiation. The present inventor also observed that the incident radiation within the photoresist layer 104 get refracted due to photoresist atoms resulting in some scattering of radiation. The above sum total effect would result in relatively low amount of acid generation near the bottom corner region of the exposed portion of the photoresist layer 104. Since the ARC is substantially chemically basic in nature, it would readily neutralize the acid that is generated in the bottom corner region of the exposed portion of the photoresist layer 104.

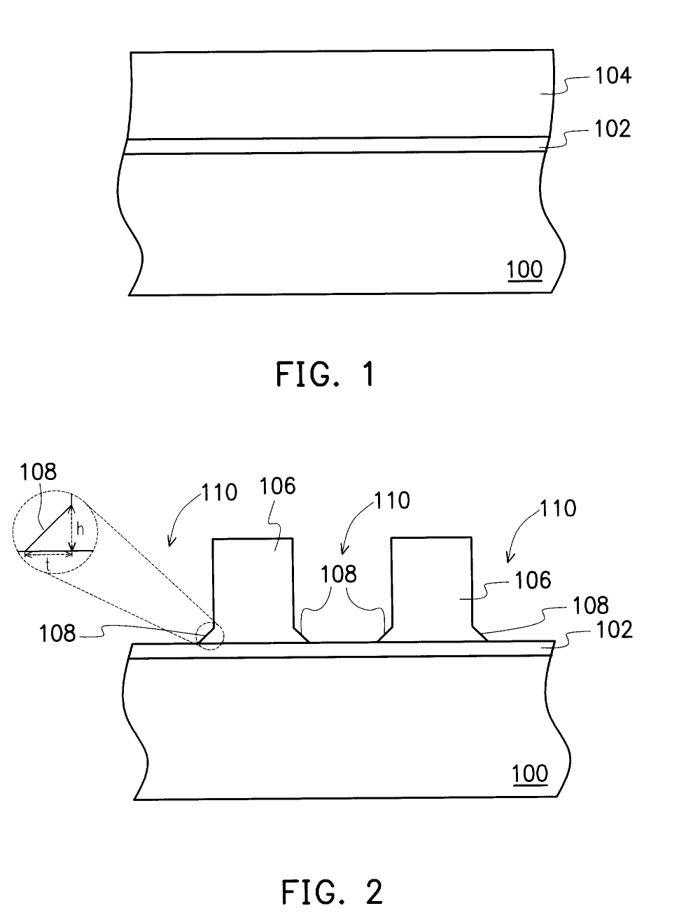

After the exposure step, the pattern is developed to selectively remove the exposed portions of the photoresist layer 104. Prior to selective removal, the exposed photoresist layer 104 may be treated (e.g., by application of heat) to enhance the property differences created by the exposure. Since the acid generated upon exposure to light radiation typically causes the exposed photoresist layer 104 composition to exhibit increased solubility in alkaline media compared to the unexposed photoresist layer 104, therefore, typically an alkaline solvent, for example KOH solution may be used for developing the photoresist layer 104. Since the neutralized portions at the bottom corner of the exposed portion is insoluble in the alkaline solvent which is used for removing the exposed portions of the photoresist layer 104, therefore, they remain intact. As a result a patterned photoresist 106 with footing structures 108 at the bottom comer as illustrated in FIG. 2, is formed, and since the ARC 102 is also insoluble in the aforesaid solvent, therefore the exposed portions of the ARC 102 remain unaffected. Openings 110 are formed over the areas where source/drain regions are to be formed.

The present inventors further observed that since the amount of acid generation during the exposure step depends on the thickness of photoresist layer 104 and the intensity of the incident radiation, therefore, the thickness of the photoresist layer 104 could be tailored to adjust the profile of the footing structure 108. Refer to FIG. 2 again, the height h of the footing structure 108 is suitably 10 Å˜1000 Å, preferably 300 Å, and the width t of the footing structure 108 is suitably 10 Å˜1000 Å, preferably 200 Å.

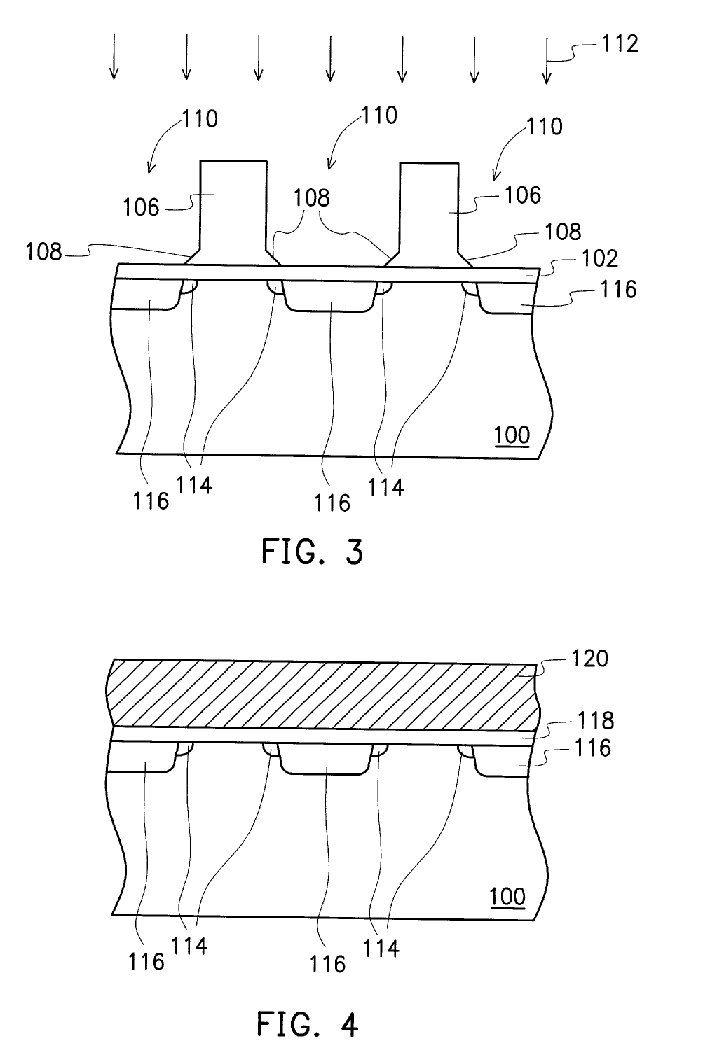

Referring to FIG. 3, according to a preferred embodiment of the present invention, an ion implantation step 112, is carried out using the patterned photoresist 106 as a mask. Because of the footing structure 108 at the bottom comer region of the photoresist pattern 106, the ions could penetrate only to a shallow depth in the region within the substrate 100 below the footing structures 108, to form a source/drain extension 114, and ions penetrate relatively into deeper depth within the substrate 100 in the areas adjacent to the footing structures 108 in the opening 110, compared to the Source/drain extension 114, to form a source/drain region 116, as best illustrated in FIG. 3. Therefore, substantially, both the source/drain extension 114, and the source/drain region 116 are formed simultaneously in a single ion implantation step.

The present inventors observed that junction depth of the source/drain extension 114 could be defined by the profile of the photoresist footing structure 108, therefore, the profile of the photoresist footing structure 108 can be tailored (by adjusting the thickness of the photoresist layer 104, as described in paragraph [0018] above) in order to form the source/drain extension 114 at a desired depth. Therefore, the present inventors provide a method of forming a source/drain extension at a desired depth, thus a MOSFET device has a desired source/drain extension junction depth. This would further facilitate to reduce or adjust the electric field near the source/drain region thus the reliability and the performance of the semiconductor device can be substantially improved.

Typically, the ion implantation step 112 is substantially a vertical ion implantation method and is carried out in the well known manner using implantation of boron fluoride, arsenic or phosphorous ions with a dose of about 5×10¹² ions/cm² to about 1×10¹⁶ ions/cm² at an energy level of about 5-200 KeV. The source/drain extension 114 and source/drain regions and 116 are then activated by heating the device to a temperature of about 800° C. to 1100° C. for 10 seconds (higher temperature) to 60 minutes (lower temperature).

Besides, materials other than photoresist can also be used to form a big-footed patterned layer like the photoresist pattern 106+108 on the substrate with any other techniques. Moreover, other methods like diffusion can also be used to introduce ions or impurities into the substrate.

After the activation of the source/drain extension and source/drain region 114 and 116, the photoresist pattern 106 and the ARC 102 are removed by using methods well known to persons skilled in the art, for example, a plasma ashing method or some chemical methods like using hot phosphoric acid or fluorine-containing chemicals. These steps are not shown in the Figs.

Referring to FIG. 4, according to a preferred embodiment of the present invention, a thin gate oxide layer 118 is thermally grown on the exposed surface of semiconductor substrate 100. The gate oxide layer 118 is typically grown in an oxygen or H₂O containing atmosphere at a temperature of about 800° C. to 900° C. Next, a gate conducting layer 120 is formed over the gate oxide layer 118. The gate conducting layer 120 includes a doped polysilicon layer. The gate conducting layer 120 is formed by depositing a layer of undoped polysilicon over the substrate 100, typically using low pressure chemical vapor deposition (LPCVD), implanting and activating impurities into the polysilicon to render it conductive. Then the gate conducting layer 120 is patterned to form a gate on the desired channel region (not shown in the FIGs.). Additionally, a thin oxide layer may be thermally grown on the control gate structures for the isolation purpose.

It is to be understood that because both the source/drain extension and source/drain region can be formed by a single ion implantation simultaneously, therefore the fabrication process is simplified and the fabrication cost can be reduced.

The present invention enables semiconductor devices to be formed having a source/drain extension and a source/drain region thereby the electric field at the source/drain region can be substantially reduced, thus the short channel effects and consequential adverse impact on device reliability, due to further device miniaturization can be effectively reduced or eliminated. In addition, the present invention is cost-efficient and can be easily integrated into conventional processing.

The present invention enjoys applicability in the manufacturing of semiconductor devices, particularly high density, multi-metal layer semiconductor devices, such as a mask read-only memory (mask ROM) device, with sub-micron features, exhibiting high speed characteristics and improved reliability.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for manufacturing a semiconductor device having a source/drain extension and a source/drain region, the method comprising the steps of:
forming a patterned layer over a substrate, wherein the patterned layer has a footing structure at a bottom corner thereof; and
introducing ions into the substrate to simultaneously form a source/drain extension and a source/drain region.

2. The method of claim 1, wherein the patterned layer comprises a photoresist pattern.

3. The method of claim 2, wherein the method of forming the photoresist pattern with the footing structure comprises the steps of:
forming a basic material layer over the substrate;
forming a acid generating photoresist layer over the basic material layer;
performing an exposure process to transfer a pattern on the acid generating photoresist layer; and
developing the exposed acid generating layer to form a photoresist pattern, wherein a footing structure is formed at a bottom corner of the photoresist pattern.

4. The method of claim 3, wherein the basic material layer comprises an antireflection coating (ARC).

5. The method of claim 4, wherein the ARC layer comprises a chemically basic bottom antireflective coating (BARC).

6. The method of claim 5, wherein the bottom antireflective coating (BARC) comprises a polymer material.

7. The method of claim 6, wherein the bottom antireflective coating (BARC) further comprises a polymer crosslinking agent, the method further comprising adjusting a concentration of the polymer crosslinking agent to control an alkalinity of the bottom antireflective coating (BARC).

8. The method of claim 6, further comprising adjusting a baking temperature of the BARC to control an alkalinity of the bottom antireflective coating (BARC).

9. The method of claim 4, wherein the ARC comprises a chemically basic dielectric anti reflection coating (DARC).

10. The method of claim 9, wherein the dielectric anti reflection coating (DARC) comprises silicon oxynitride (SiOₓN_{y}).

11. The method of claim 10, further comprising adjusting the ratio of x to y to control an alkalinity of the dielectric anti reflection coating (DARC).

12. The method of claim 10, further comprising performing a surface treatment with an O₂ plasma to control an alkalinity of the dielectric anti reflection coating (DARC).

13. The method of claim 1, wherein introducing ions into the substrate comprises implanting ions into the substrate.

14. A method of forming a photoresist pattern, the method comprising the steps of:
forming a acid generating photoresist layer over an ARC, wherein the ARC is substantially chemically basic in nature;
exposing the acid generating photoresist layer with a light radiation; and
developing the exposed acid generating photoresist layer to form a photoresist pattern, wherein a footing pattern is formed at a bottom corner of the photoresist pattern.

15. The method of claim 14, wherein the ARC comprises a chemically basic bottom antireflection coating (BARC).

16. The method of claim 14, wherein the ARC comprises a chemically basic dielectric antireflection coating (DARC).

17. A method of manufacturing a mask read-only-memory device, the method comprising the steps of:
providing a substrate;
forming a photoresist pattern having a footing structure at a bottom corner of the photoresist pattern;
performing an ion implantation using the photoresist pattern as a mask to simultaneously form a source/drain extension and a source/drain region within the substrate;
removing the photoresist pattern;
forming a gate oxide layer over the substrate; and
forming a gate over the gate oxide layer.

18. The method of claim 17, wherein the method of forming the photoresist pattern comprises the steps of:
transforming the surface of the substrate to substantially chemically basic;
forming a acid generating photoresist layer over the substrate;
performing an exposure process to transfer a pattern on the acid generating photoresist layer; and
performing a developing process to form a photoresist pattern, wherein a footing structure is formed at a bottom corner of the photoresist pattern.

19. The method of claim 17, wherein the method of forming the photoresist pattern comprises the steps of:
forming a chemically basic material layer over the substrate;
forming a acid generating photoresist layer over the chemically basic material layer;
performing an exposure process to transfer a pattern on the acid generating photoresist layer; and
performing a developing process to form a photoresist pattern, wherein a footing structure is formed at a bottom corner of the photoresist pattern.

20. The method of claim 19, wherein the chemically basic material layer comprises an anti-reflection coating (ARC).

21. The method of claim 20, wherein the ARC comprises a chemically basic bottom antireflection coating (BARC).

22. The method of claim 20, wherein the ARC comprises a chemically basic dielectric antireflection coating (DARC).
